(19) United States
(12) Patent Application Publication
(10) Pub. No.: US 2010/0308849 A1
(43) Pub. Date: Dec. 9, 2010

(54) DEVICE FOR DETECTING RADIAL CRACKS IN A PARTICULATE FILTER

(75) Inventors: Bernard Bouteiller, L'Isle Sur La Sorgue (FR); Arnaud Ballon, Cavaillon (FR); Anthony Briot, Saint Saturnin Les Avignon (FR); Gaetan Champagne, L'Islesur La Savgue (FR); David Pinturaud, Cavaillon (FR)

Correspondence Address: OBLON, SPIVAK, MCCLELLAND MAIER & NEUSTADT, L.L.P., 1940 DUKE STREET, ALEXANDRIA, VA, 22314, US

(73) Assignee: SAINT-GOBAIN CENTRE DE RECHERCHES ET D'ETUDES EUR., Courbevoie (FR)

(21) Appl. No.: 12/808,949

(22) PCT Filed: Dec. 19, 2008
(86) PCT No.: PCT/FR08/52391

§ 371 Date: Jun. 17, 2010

(30) Foreign Application Priority Data
Dec. 21, 2007 (FR) 0760202

(51) Int. Cl. G01R 27/08

(52) U.S. Cl. 324/700

(57) ABSTRACT

The invention relates to an assembly consisting of a device for detecting radial cracks in a particulate filter of the honeycomb type, of which the filtering part is made up of a porous inorganic material, said particulate filter comprising a single monolithic element or being obtained by combining a plurality of monolithic elements, the device being characterized in that it comprises an electrically conducting material arranged in the form of a strip or of a wire on at least one longitudinal part of the filter, secured to a monolithic element and/or to the coating cement or the jointing cement, and having an electrical conductivity greater than that of the material that makes up that part of the filter to which it is secured, and a strength less than or equal to that of the material that constitutes that part of the filter to which it is secured, and means of measuring the conductivity or the electrical resistance of the strip or wire of electrically conducting material.

The invention relates to the field of particulate filters particularly used in an exhaust line of an engine to eliminate the soot which is produced by the burning of a diesel fuel oil in an internal combustion engine. More specifically, the invention relates to a device for detecting radial cracks in a honeycomb particulate filter particularly used in an exhaust line of an internal combustion engine in an automobile or a truck or a stationary system.

Filtration structures for filtering the soot contained in the exhaust gases of internal combustion engines are well known in the prior art. These structures usually have a honeycomb structure, one of the faces of the structure being to admit the exhaust gases that are to be filtered and the other face being to discharge the filtered exhaust gases. The structure comprises, between the admission and discharge faces, a collection of adjacent ducts with mutually parallel axes separated by porous filtering walls, which ducts are closed off at one or other of their ends in order to delimit inlet chambers opening onto the admission face and outlet chambers opening onto the discharge face. To ensure a good seal, the peripheral part of the structure may be surrounded by a cement, known as coating cement or external coating in the remainder of this description.

The channels are alternately closed off in an order such that that the exhaust gases, as they pass through the honeycomb body are forced through the lateral walls of the inlet channels in order to access the outlet channels. In this way, the particles or soot become deposited and build up on the porous walls of the filter body. Usually, the filtering bodies are based on a porous ceramic material, for example cordierite or silicon carbide or aluminum titanate.

In a known way, during its use, the particulate filter is subjected to a succession of filtration phases (in which soot accumulates) and regeneration phases (in which the soot is eliminated). During the filtration phases, the particles of soot emitted by the engine are caught and become deposited within the filter. During regeneration phases, the particles of soot are burnt inside the filter, in order to restore to the latter its filtration properties. The porous structure is therefore subjected to intense thermal and mechanical stresses, which may lead to microcracks liable, over time, to lead to a severe loss in filtration capability of the unit, or even completely deactivate it. This phenomenon is seen in particular in large-diameter or long-length monolithic filters.

In order to solve these problems and increase the life of the filters, there have more recently being proposed more complex filtration structures that combine into a filtering unit several monolithic honeycomb elements. The elements are usually joined together by bonding using a cement of a ceramic nature, known in the remainder of this description as jointing cement. Examples of such filtering structures are, for example, described in patent applications EP 816 065, EP 1 142 619, EP 1 455 923, WO 2004/090294 or alternatively WO 2005/063462. It is known that, in this type of structure, in order to ensure better relaxation of the stresses, the thermal expansion coefficients of the various parts of the structure (filtering elements, coating cement, jointing cement) need to be of substantially the same order of magnitude. As a result, said parts are synthesized on the basis of one and the same material, usually silicon carbide SiC or cordierite or aluminum titanate. This choice also makes it possible to even out the distribution of heat during filter regeneration. What is meant by “on the basis of one and the same material” within the meaning of the present description is that the said material constitutes at least 25 wt %, preferably at least 45 wt % and more preferably still at least 70 wt % of said material.

Soot filters as previously described are chiefly used on a large scale in devices for reducing the pollution of the exhaust gases of a diesel fuel oil combustion engine in automobiles or trucks or stationary systems.

At the present time, in spite of the improvements made, filtration structures are not yet entirely reliable throughout the life of the motor vehicle. Thus, in the case of certain materials the mechanical strength of which is relatively low, such as cordierite, it is fairly frequent for radial cracks to appear during poorly controlled regeneration or alternatively during spontaneous regeneration in the filter. During such uncontrolled phases, the local temperature of the filter may reach temperatures in excess of 800° C., with a great deal of spatial inhomogeneity in the temperatures, leading to the appearance of cracks which have a fairly great impact on the integrity and filtration capability of the filter.

Quite specifically, experience has shown that in the severest of cases, large-scale radial cracks that may cover the entire filter may appear.

Such cracks, often known in the art as “ring off” cracks, develop in a radial plane across a section of the filter. Because of substantial temperature difference between the center and the periphery of the filter during regeneration phases or under transient conditions (particularly when the engine is accelerating, for example in the case of overtaking (passing) or rapid heating of the engine, for example when climbing or descending a hill), it is commonly accepted that these begin in the peripheral part of the monolithic filter or assembly and then propagate typically in the radial direction toward the center of the filter, although such a mechanism has not been established definitively. These cracks are therefore connected with the appearance of thermal gradients across the filter and appear in all types of filter, even those with the best thermomechanical strength, such as SiC filters, penalized by a relatively high thermal expansion coefficient. Furthermore, the pressure applied by the metal canning may add mechanical stresses that are iso-radial with respect to the axis of the filter and liable to exacerbate the cracking phenomenon. This type of cracking may in particular lead, over the life of the filter, to the filter splitting into two parts, this leading to a sudden and sharp drop in the filtration capability, which incidentally is unacceptable with respect to present-day emission standards. What is more, contamination of depollution members downstream of the filter with unfiltered soot may combine with this sharp reduction in filtration capability. The damage to the filter, which loses its pressure drop characteristics, also leads to problems with regulating the operation of the engine when this engine is regulated according to a minimum pressure drop threshold.

As described previously, the thermal gradients occur during filter regeneration, particularly during the increase in temperature associated with the burning of the soot: the mean filter temperature then ranges between 400 and 1300° C. The filter temperature is generally higher at the center than at the periphery of the filter. This gradient varies according to the physical and thermal characteristics of the filter. A phenomenon such as this is described for example in publication SAE 2006-01-1527 to which reference may be made according to the invention. The problem of the appearance of radial cracks known as ring-off cracks is all the greater, for the same thermal gradient, for a monolithic filter made using a material the coefficient of expansion of which is high in relation to its mechanical strength properties.

According to another aspect and in specific applications of particulate filters to heavy goods vehicles or applications that use an additive to assist with regeneration, for example of the cerine type, the particular filters have to be removed periodically from the exhaust line so that they can be cleaned with the filtering device in order to remove any unburnt residue of combustion and extend their life. This operation generally consists in chemical treatments (selective chemical attack of the residue deposit) and/or mechanical treatments (blowing air or liquid through the outlet channels), in the hot state or at ambient temperature. The stresses applied during this cleaning may also lead to damage to the filter and assist with initiating and/or propagating cracks of the ring-off type which have been initiated during previous use in the exhaust line. Filters thus damaged after cleaning, when reinstalled in the vehicle, may then display the same disadvantages as those described hereinabove (that is to say problems with filtration effectiveness, pressure drop, etc.), with the same consequences.

In order to avoid these problems, and this is what forms the subject of the present invention, it is necessary to have available a simple and effective system for detecting the existence of such cracks and to do so as soon as they begin and/or propagate, in order to prevent catastrophic failure of the filter and premature filter change at the dealership. According to another aspect, the detection device according to the invention also makes it possible to determine the origin of the fault.

Methods for detecting cracks using imaging on a canned or uncanned filter are known from the prior art. Application EP 1 369 161 A1 describes an example of these systems, using tomography or X-rays and/or ultrasonic testing. These systems cannot, however, be used in an in-vehicle setting. In addition, they present problems of space or even problems of safety which are associated with the presence of a radioactive source. Endoscopy techniques are also known but are intrusive.

Electrically conducting systems aimed, either in the jointing cement or in the external coating, at reducing the thermal gradient experienced by the filter particularly during the regeneration phase, are also known. These systems have high resistivity in order to obtain heating through a Joule effect. However, they do not make it possible to detect the onset and/or propagation of cracks.

There is therefore at the present time a need for a device for detecting radial cracks known as “ring off” cracks that is simple, effective and non-intrusive and can be applied to any type of filter, monolithic or assembled, regardless of the material on which said filter is based. The invention relates to such a device which also has the advantage that it can be applied directly to a particulate filter while it is in use, that is to say directly on the motor vehicle exhaust line. According to another aspect, the device according to the invention makes it possible simply and immediately to check the integrity of a filter outside of the exhaust line, for example following a residue elimination phase on a heavy goods vehicle filter.

More specifically, the present invention relates to an assembly consisting of a device for detecting radial cracks in a particulate filter of the honeycomb type, of which the filtering part is made up of a porous inorganic material, said particulate filter comprising a single monolithic element or being obtained by combining, by bonding using a jointing cement, a plurality of monolithic honeycomb elements, it being possible also for said filter to be covered with a coating cement, the device comprising:
an electrically conducting material arranged in the form of a strip or of a wire on at least one longitudinal part of the filter, said conducting material being secured to a monolithic element and/or to the coating cement or the jointing cement, said conducting material having an electrical conductivity greater than that of the material that makes up that part of the filter to which it is secured, and a strength, particularly at a temperature of between ambient temperature and 1200° C., less than or equal to that of the material the constitutes that part of the filter to which it is secured,
means of measuring the conductivity or the electrical resistance of the strip or wire of electrically conducting material.

Said part of the filter that is secured to the strip or wire of conducting material is therefore either a monolithic element or the coating cement or the jointing cement or a combination of several of these parts, depending on where the strip or the wire is positioned.

For example, the strip or wire of conducting material is arranged in at least a central position along the length of the filter and preferably in a peripheral position along the radius or width of the filter.

For preference, the resistance of the electrically conducting material, measured in ohms is at least 10 times smaller than that of the material constituting that part of the filter to which it is secured, at a temperature of 800° C. or below, and preferably at least 100 times lower than that of the material that constitutes that part of the filter to which it is secured, at a temperature of 600° C. or below.

Typically, the ratio of the modulus of rupture to the modulus of elasticity of the electrically conducting material is at least 1.1 times lower than that of the material that constitutes that part of the filter to which it is secured and preferably at least 2 times lower than that of the material that constitutes that part of the filter to which it is secured.

The electrically conducting material that constitutes the strip or the wire comprises at least one element chosen from the group consisting of metallic or ceramic conductors.

According to one possible embodiment of the invention, the electrically conducting material consists of a metallic wire or tape arranged in contact with and secured to a monolithic element and/or, for preference, the coating cement or the jointing cement, particularly wires of the Chromel® or Alumel® or Inconel® type, or made of some other refractory metal.

According to another embodiment, the electrically conducting material consists of a strip of a ceramic material comprising particles of an electrically conducting material chosen from metals of the Fe, Ni, Si, Cr, W group, metal alloys particularly Alumel, Inconel, NiCr, FeCr, SiCr, MoSi₂, or metal oxides of the Sfo₂, Fe₂O₃ type, or metal carbides, particularly WC, B₄C, SiC, or alternatively electrically conducting carbon such as graphite. In this embodiment, the ceramic material that constitutes the electrically conducting material may be based on the same material as the material that constitutes that part of the filter to which it is secured.

According to an alternative embodiment, the electrically conducting material consists of a strip of an array of percolating conducting particles deposited on the material that constitutes the filter to which it is secured, said particles being chosen preferably from metals of the Fe, Ni, Si, Cr, W group, metal alloys, particularly Alumel, Inconel, NiCr, FeCr, SiCr, MoSi₂, or metal oxides such as SnO₂, Fe₂O₃, or certain metal carbides, particularly WC, B₄C, SiC, or alternatively electrically conducting carbon such as graphite.

According to the invention, the wire or strip of conducting material may be arranged at the periphery of the coating cement or embedded within the coating cement.

In an embodiment in which the filter consists of a plurality of monolithic honeycomb elements bonded together using a jointing cement, the wire or strip of conducting material may also be arranged at the periphery of the jointing cement or embedded in the jointing cement.

Without departing from the scope of the invention, the wire or strip of conducting material is arranged in contact with or inside the filtering part of the filter.

For example, said element or elements, the coating cement and the jointing cement are based on one and the same ceramic material, preferably one based on silicon carbide SiC.

The invention also relates to a method of detecting radial cracks in a particulate filter of the honeycomb type, using a device as described hereinabove, in which the means of measuring the conductivity or electrical resistance of the strip or of the electric wire of conducting material are configured to:
measure a parameter chosen from among a voltage measurement, an AC or DC current measurement or measurement of the electrical resistance, for example at an imposed voltage, it being possible for the measurement to be taken continuously or at various predefined instants, for example at the start of the life of the filter in order to calibrate it; before, during or after regeneration; upon start-up of the vehicle equipped with a filter; in a predefined temperature range,
compare the value obtained against a threshold value for detection of a radial crack known as a “ring off” crack,
activate a signal to warn the driver or the operator that said cracks have appeared.

The means of measuring the conductivity or the electrical resistance of the strip or of the electric wire of conducting material may also be configured to:
perform a comparison against a threshold value that is predefined, by means of a computer or of an electronic module connected to the engine control system,
modify, as a function of said comparison, the engine management parameters or filter regeneration management device parameters in order to reduce the stress on the filter, particularly by lowering the temperature at the inlet to the filter or reducing the oxygen content upstream of the filter.

The means of measuring the conductivity or electrical resistance of the strip or of the electric wire of conducting material may also be configured to:
perform a comparison against a threshold value that is predefined, by means of a computer or of an electronic module connected to the filter regeneration system,
modify, as a function of said comparison, the management parameters of the filter regeneration system particularly by reducing the limiting mass of soot.

According to the invention and as described hereinabove, the strip or wire of electrically conducting material has of necessity to have an electric resistance less (in the temperature range in which the measurement is taken) than that part of the filter to which it is secured. For example, if the strip or the wire is positioned between a monolithic element and the external coating, its electrical resistance needs to be appreciably lower than that of the materials that constitute the filter and said coating. If the strip or the wire is positioned in contact with the external coating of the filter, then it needs to have a resistance lower than that of the material that constitutes the coating, or even lower than the fibrous thermal insulation positioned between the filter and the metal can.

The properties of the strip or wire of conducting material according to the invention are chosen as a function of the materials that constitute the filter equipped therewith. In particular, the strip or wire is made of a material of which mechanical breakage, at the service temperature, occurs at a level of thermomechanical stress that is equivalent to or lower than the level of stress in the porous inorganic material that constitutes the filter. A property such as this ultimately allows reliable detection of cracks of the ring off type in the filter. Thus, the invention is to be understood as relating to any configuration of the device as described hereinabove, provided that the strip or wire has a mechanical strength less than or equal to that of the material that constitutes the filtering part of the filter under the normal conditions of use of the filter and preferably at a temperature of between ambient temperature and 1200° C. According to the invention, the level of mechanical strength of the conducting material of the strip or of the wire can therefore vary and is chosen as a function of the material that constitutes the filter. Thus, the conducting material used in the case of cordierite will differ from that used for recrystallized SiC, which has a far higher thermomechanical and mechanical strength. Other parameters such as the geometry of the filter (particularly the shape of filter, the shape of the channels, the thickness of the filtering walls and, more generally, any geometric component that influences the mechanical strength of the filter) may also be taken into consideration when selecting the conducting material according to the invention, together with the conditions of use of said filter and particularly the temperature at which it is cleaned in the case of truck filters.

Furthermore, it is also preferable according to the invention for the material that constitutes the electric conductor to have a ratio of modulus of rupture to modulus of elasticity close to that of the material that constitutes the filter.

According to another aspect of the invention, the strip or wire of conducting material according to the invention is chosen so that it does not introduce any additional stress into the filter and so that it remains secured to the monolithic element or to the coating cement or to the jointing cement under normal conditions of use of the filter.

Within the meaning of the present invention, the strip or the wire and the monolithic element or the coating cement or the jointing cement are understood to be secured to one another if they are in close enough contact that the assembly remains connected, regardless of the mechanical or thermomechanical stresses applied to them, particularly under normal conditions of use of the filter and more especially during successive regeneration phases.

In particular, it is preferable according to the invention for the conducting material that constitutes the strip or wire to have a coefficient of expansion that is as close as possible to that of the porous material that constitutes the filtering part.

Reliable results can thus be obtained according to the invention, for the following configurations:

1) The electrically conducting material is incorporated into the filter in the following form:
one or more metal or ceramic wires or tapes in contact with and secured to the filter or the coating, particularly wires of the Chromel® or Alumel® or Inconel® type or made of some other refractory metal.
a coating with electrically conducting particles deposited on a longitudinal part of the filter, on the filter coating, the jointing cement of the filter or in one or more filter channels. In particular, the best results in terms of reliability have been had when the electrically conducting material is obtained by depositing percolating particles of an electrically conducting material chosen from metals of the Fe, Ni, Si, Cr, W group, metal alloys (particularly Alumel, Inconel, NiCr, FeCr, SiCr, MoSi₂), or metal oxides (SnO₂, Fe₂O₃, etc.) or certain metal carbides (particularly WC, B₄C, SiC), alternatively electrically conducting carbon (graphite).
an electrically conducting cement incorporating the particles of electrically conducting material as described hereinabove, said cement then being arranged on the filter in a strip and secured to a monolithic element of the filter, to the external coating or to the bonding joint. Typically, the ceramic material that constitutes the electrically conducting material is then based on the same material as the material that constitutes the part of the filter to which it is secured, that is to say the material that constitutes the jointing cement, the external coating or the filtering part of the filter.

2) The conducting strip or wire is preferably arranged along the entire length in the central zone of the filter or more generally in the zone where cracking most likely occurs, provided that contact with the measuring system can be contrived.

3) One of the following geometries is adopted for good connection of the electric strip or wire:
positioned on the external coating
embedded in the external coating
embedded in the thickness of the bonding jointing cement in the case of an assembled filter
positioned in the filter channels.

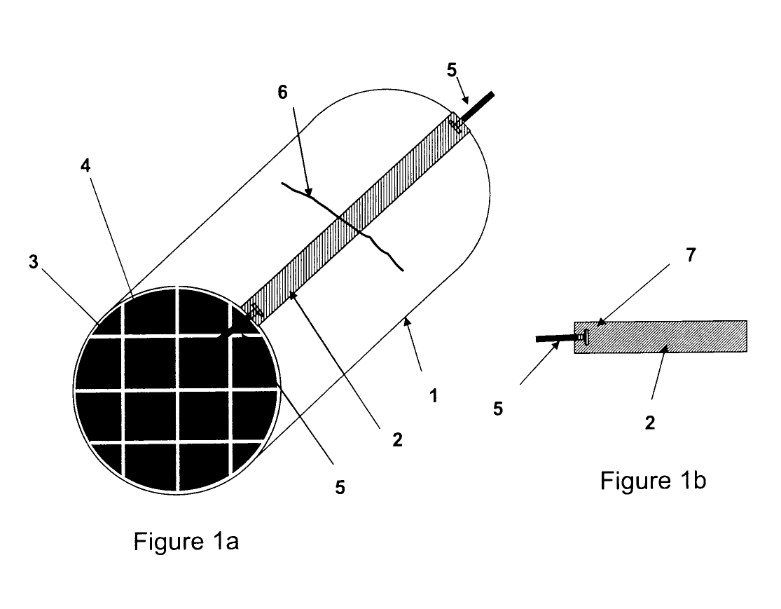

FIGS. 1 to 9, which do not limit the scope of the present invention, are given purely by way of illustration and to provide a better understanding of the invention and of some of the embodiments thereof.

FIGS. 1a and 1b illustrate a first embodiment of a filter equipped according to the invention with a strip of an electrically conducting material.

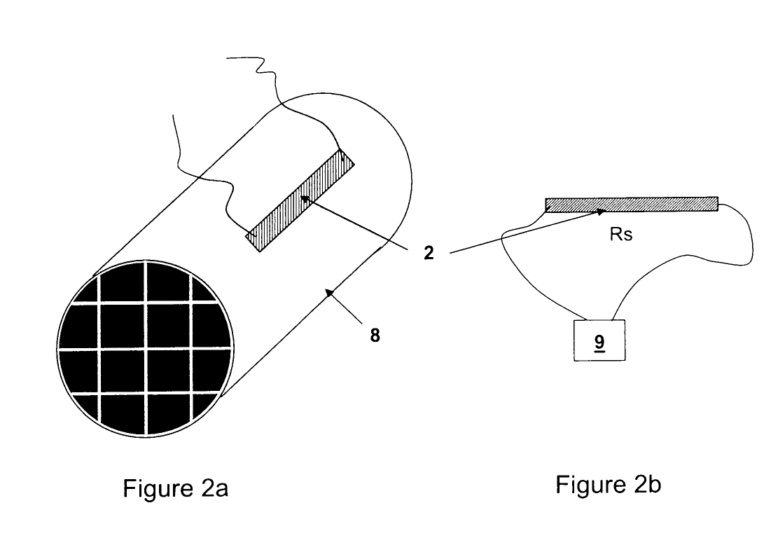

FIGS. 2a and 2b illustrate, by way of alternative, another embodiment in which the conducting strip is present only in a central part of the filter.

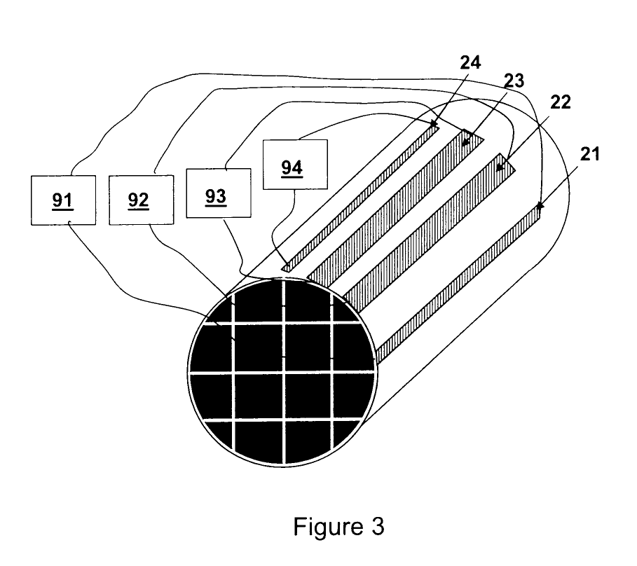

FIG. 3 illustrates an embodiment in which several conducting strips, operating independently, are positioned at the surface of the filter.

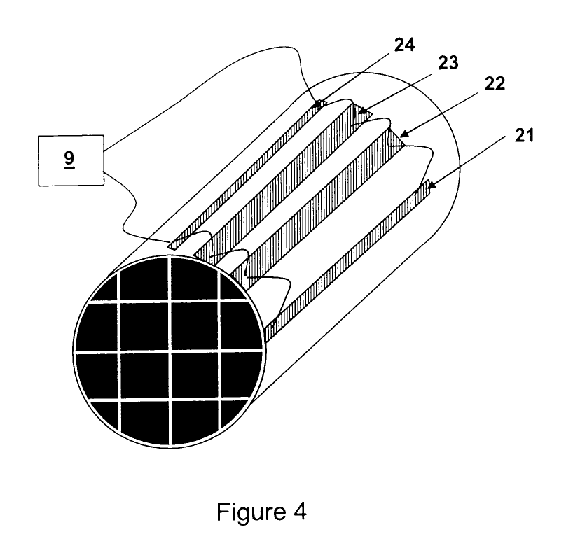

FIG. 4 illustrates an alternative to the previous embodiment, in which the successive strips are connected together to constitute a system of parallel resistors.

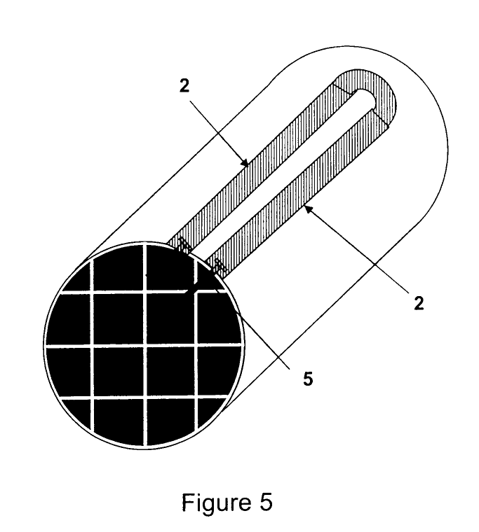

FIG. 5 illustrates an embodiment in which the strip has a horseshoe or U-shape, the electrodes that connect to the measuring device being positioned on one and the same face of the filter.

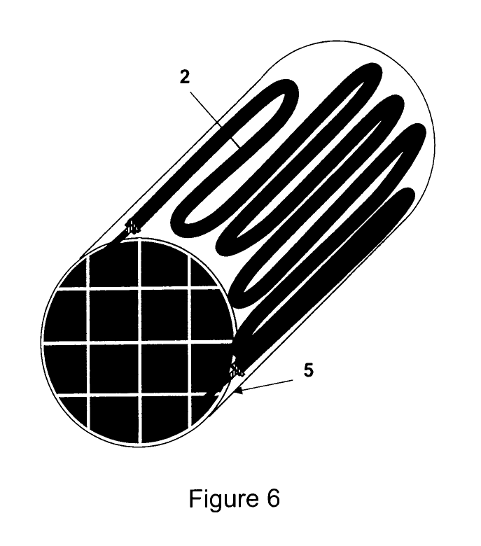

FIG. 6 illustrates an alternative form to the preceding one, in which the strip of conducting material has a spiral-wound shape in order to cover most of the surface of the filter.

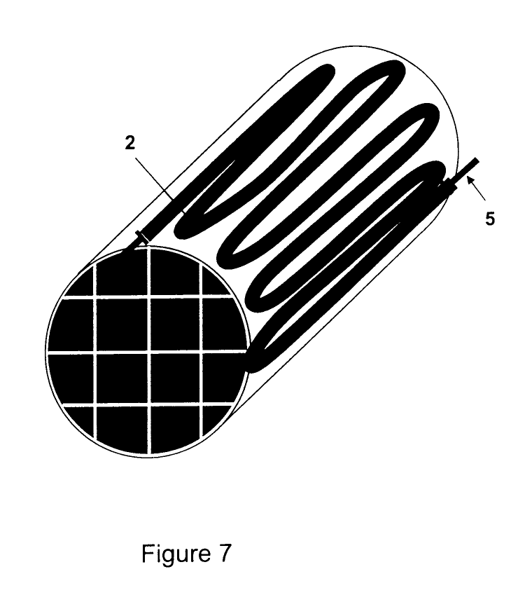

FIG. 7 depicts an embodiment identical to the previous one but in which the electrodes for connecting to the measurement device are positioned on opposite faces of the filter.

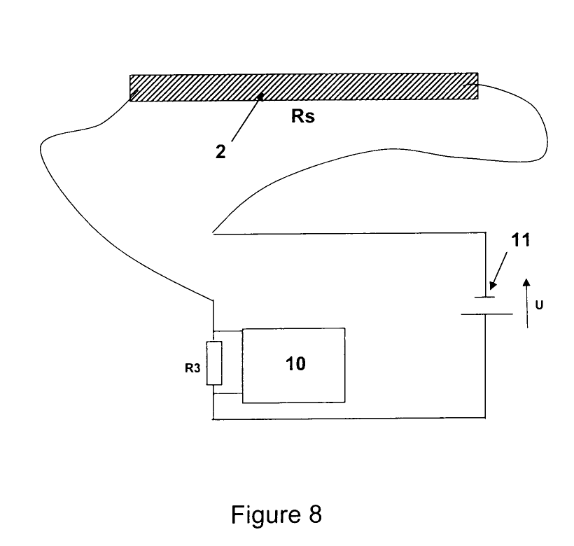

FIG. 8 schematically depicts a first configuration of a device for measuring the resistance Rs of the conducting strip.

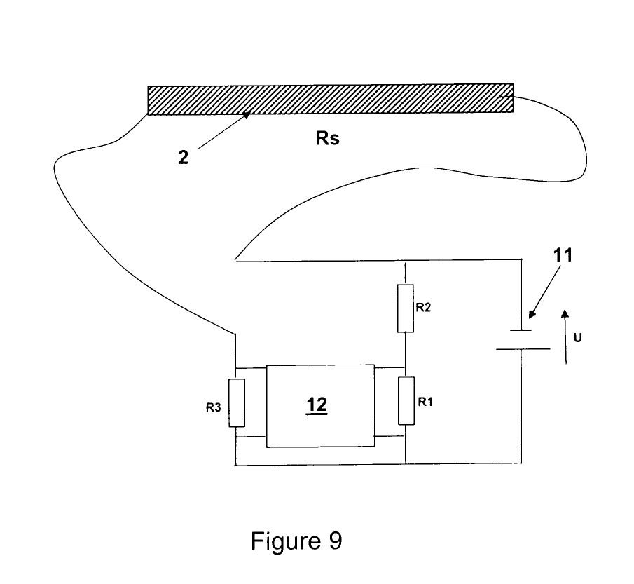

FIG. 9 schematically depicts a second configuration of a device for measuring the resistance Rs of the conducting strip.

FIG. 1a depicts an overall view of a filter 1 equipped with a conducting strip 2 according to the invention. As depicted in FIG. 1a, the conducting strip consists of a conducting material as previously described, deposited in the form of a layer covering the external coating of the filter. Of course, this does not, however, place any limitation on the present invention, and the strip may be arranged at other points on the filter, as previously described.

The filter depicted in FIG. 1a is an assembled filter obtained by assembling, using a jointing cement 3, monolithic elements 4 consisting of a porous inorganic material such as SiC or cordierite or aluminum titanate, conventionally in the form of a honeycomb structure. Connectors 5 are positioned on each side of the conducting strip 2.

In operation, the connectors 5 are in contact with the conducting strip and are connected to an apparatus for measuring the electrical conductivity or the electrical resistance of the conducting strip 2 (this apparatus is not depicted in FIG. 1, see FIG. 8 or 9). Breakage of the filter at the coating cement in the form of a radial crack 6 known as a ring off crack, also leads to breakage of the conducting strip 2 secured to it, and to discontinuity in the electrical measurement. This discontinuity makes it possible according to the invention reliably to detect the cracking of the filter.

According to the invention, electrical contact between the connector 5 and the conducting strip 2 may be achieved by any known and appropriate welding or brazing technique, particularly if the conductor is a metal tape or wire, or using techniques of anchoring or coating the connector in the electric conductor if the latter is, for example, a conducting cement, or alternatively by bonding using a ceramic or temperature-resistant adhesive. As depicted in FIG. 1b, the connectors 5 advantageously have a T-shaped end 7 which prevents any detachment of the strip 2.

According to the invention, in such a configuration, means of protecting the connectors and the cables that connect them to the measurement system may be provided, in order to insulate them electrically from the can surrounding the filter in the exhaust line and protect them against temperature, if need be, or even protect them against the corrosive atmosphere of the exhaust gases.

FIGS. 2a and 2b depict another embodiment in which the conducting strip 2 is present only in the central part 8 of the filter. The conducting strip of resistance Rs is, in the simplest way, connected to a conventional device 9 for measuring resistance, for example by continuously measuring said resistance Rs under an imposed voltage.

FIG. 3 schematically depicts an embodiment similar to the preceding one but in which several resistances 21 to 24 are used, each connected to resistance-measuring devices 91 to 94. This arrangement additionally makes it possible to evaluate the change in and propagation of the “ring off” crack or cracks in the filter.

FIG. 4 depicts an embodiment that differs from the preceding one in that the strips 21 to 24 are arranged according to the configuration of an electrical system with several resistors mounted in parallel, each strip acting like one resistor. This embodiment therefore also makes it possible to evaluate the change and propagation of the “ring off” crack or cracks in the filter, an increase in the resistance measured by the device 9 corresponding to each crack in a strip.

FIGS. 5 to 7 depict various embodiments whereby the strip 2 is able to cover a more comprehensive area of the surface of a filter, thus allowing cracking to be detected even earlier on, wherever it may appear.

FIG. 8 illustrates a first embodiment for measuring the resistance Rs of the conducting strip 2. The latter is placed in series with a resistor R3 in a circuit powered at a set voltage by a generator 11, for example the battery of the vehicle if the system is an in-vehicle system.

If the strip 2 breaks, the sudden increase in the resistance Rs allows immediate detection of the anomaly via a voltmeter 10.

FIG. 9 illustrates another embodiment of the device for measuring the resistance Rs of the conducting strip 2. As described previously, the conducting strip 2 is placed in series with a resistor R3 in a circuit powered at a set voltage by a generator 11, for example the battery of the vehicle if the system is an in-vehicle system. The electrical voltage at the terminals of the resistor R3 is compared, by the voltage comparator 12, against the electric voltage at the terminals of the resistor R1. Preferably, in order to facilitate the measurement, the resistances of the resistors R1 and R3 are chosen to be substantially equal. Likewise, the resistance of the resistor R2 is chosen to be close to the resistance created by the collection of conducting strips 2 and connectors 5. As an even greater preference, the resistances of the resistors R1, R2 and R3 are equal and chosen so that they are very close to the resistance created by the collection of conducting strips 2 and connectors 5. When there is a breakage or damage to the strip 2, the voltage at the terminals of R3 drops and becomes very much different than R1, the appearance of a crack then being immediately detected by the voltage comparator 12.

The invention and the advantages thereof will be better understood from reading the examples that follow. Of course, these examples must not be considered, in any of the aspects described, to limit the present invention.

### Example 1

A filtering structure comprising an assembly of filtering elements made of silicon carbide connected by a jointing cement were synthesized in accordance with the techniques described in patent EP 1 142 619 A1.

Sixteen monolithic filtering elements of square cross section made of recrystallized SiC were first of all extruded, dried then baked in accordance with well known techniques, for example those described in EP 1 142 619.

A jointing (and coating) cement was then prepared by mixing:
85 wt % of SiC powder with a particle size ranging between 10 and 200 μm,
4 wt % of a calcined alumina powder marketed by the company Almatis,
10 wt % of a reactive alumina powder marketed by the company Almatis,
0.9 wt % of a temporary and plasticizing binder of the cellulose type,
0.1 wt % of a deflocculant of the STPP (sodium tripolyphosphate) type.

An amount of water corresponding to 10% of the weight of this mixture was added in order to obtain a cement of appropriate viscosity.

After the monoliths had been assembled using said cement, the structure was machined on its exterior surface in order to obtain a cylindrical structure with a diameter of about 144 mm. A slurry based on SiC, mixed with electrically conducting grains of MoSi₂ (supplied by the company Goodfellow SARL was applied to this structure, said grains of MoSi₂ being characterized by a median diameter of the order of 45 μm and a purity of 99.5%, with the addition of a dispersant of STPP (sodium tripolyphosphate) type and an organic binder of the cellulose type in a content of 0.5 wt % with respect to the amount of MoSi₂ powder. This mixture was moistened with the addition of water at a content of about 10% with respect to the amount of MoSi₂ powder present and adapted to obtain a viscosity suited to good spreading of the cement and a good coverage of the support.

The deposit of slurry was performed in such a way as to obtain a longitudinal strip at the surface of the structure as illustrated by FIG. 2. A deposit in a peripheral filtration channel advantageously provides better control over the continuity of the electric conducting film. An electrode a few centimeters long and in the shape of a 0.5 mm tube made of a refractory metal of the inconel type was affixed at each end of the filter in the strip of conducting cement in order to ensure good electrical contact. A T-shaped shoulder was produced at the end of the electrode in order to prevent any decohesion during the subsequent steps of manufacture and use and allow better anchorage of the electrode in the conducting cement. The structure was dried at 110° C. in order to cure the conducting cement. The dried structure was then covered with the same cement as had already been used to manufacture the joints between the monolithic elements.

The assembly was annealed at a high enough temperature to ensure satisfactory cohesion of the filter and of its elements and to cure the protective external coating.

The characteristics of the raw filtration structure thus synthesized are collated in table 1.

TABLE 1
Characteristics of the raw structure

| Channel geometry | Square |
|---|---|
| Channel density | 180 cpsi |
| | (channels per square inch, |
| | 1 inch = 2.54 cm) |
| Wall thickness | 350 μm |
| Number of assembled elements | 16 |
| Shape of structure | cylindrical |
| Length | 10″ (25.4 cm) |
| volume | 4.12 liters |

The filter was then inserted into its can (the term of the art “canning” is widely used) with a thermally insulating fibrous mat between the filter and metal canning. Each electrode was connected by welding to an electric cable suited to high temperature applications, particularly with an alumina-based thermally and electrically insulating sheath. Each cable passed through the canning via a gland and was brought into contact with an ohmmeter.

The resistance at the terminals of the filter consisting of the conductor, the electrodes and the ceramic strip is the reference resistance.

The filter thus was mounted with its canning instrumented with its detection device on an engine test rig equipped with a means of measuring pressure drop, so as to reproduce an exhaust line, ideally one corresponding to that with which the vehicle that will have the format of filter thus characterized will be equipped.

The filter was filled with soot at 4 g/l of filter in accordance with the procedure well known to those skilled in art.

The filter thus laden was mounted on an exhaust line of an engine, for example a PSA 2 l fuel-injected diesel engine of the DW10A type, in order to undergo regeneration defined as follows: after stabilizing at an engine speed of 1700 revolutions/minute at a torque of 95 Nm for 2 minutes, a post-injection was performed at a 70° phase shift for a post-injection delivery of 18 mm³/shot. Once the burning of the soot had been initiated, more specifically once the pressure drop had decreased for at least 4 seconds, the engine speed was lowered to 1050 revolutions/minute for a torque of 40 Nm for 5 minutes in order to speed the combustion of the soot. The filter was then subjected to an engine speed of 4000 revolutions/minute for 30 minutes in order to eliminate the remaining soot.

Resistance was measured continuously and the inventors were unable to observe any increase in the resistance outside of the variation associated with the change in the resistance of the filter as a function of temperature.

The filter was then removed from its canning and the inventors found no cracks of the ring off type.

The filter was refitted into its canning under the same conditions as before and then filled with soot at 12 g/liter of filter and subjected to a severe regeneration test under the same conditions as before.

Resistance was measured continuously and the inventors were able to observe a sharp increase in the resistance at the terminals of the filter during the engine phase at an engine speed of 1050 revolutions per minute, that is to say at the instant the soot began to burn and the onset of a high amplitude radial thermal gradient in the filter. The filter was then removed from its canning and the inventors were able to observe the presence of a crack of the “ring off” type, responsible for the break in the conducting strip.

1. An assembly having a device for detecting one or more radial cracks in a particulate filter of honeycomb structure, wherein a filtering part of the filter comprises a porous inorganic material, said particulate filter comprising a single monolithic element or a plurality of monolithic honeycomb elements bonded by a jointing cement, and optionally covered with a coating cement, the device comprising:
an electrically conducting material arranged in the form of a strip or of a wire on at least one longitudinal part of the filter, said conducting material being secured to at least one of the monolithic element, the coating cement and the jointing cement, said conducting material having an electrical conductivity greater than an electrical conductivity of a material of the part of the filter to which the conducting material is secured, and a strength of the conducting material, at a temperature of between ambient temperature and 1200° C., less than or equal to a strength of the material of the part of the filter to which the conducting material is secured,
a comparator measuring the conductivity or an electrical resistance of the strip or wire of electrically conducting material.

2. The assembly as claimed in claim 1, wherein the strip or wire of conducting material is arranged in at least a central position along the length of the filter.

3. The assembly as claimed in claim 1, wherein the resistance of the electrically conducting material, measured in ohms is at least 10 times smaller than the resistance of the material of the part of the filter to which the conducting material is secured, at a temperature of 800° C. or below.

4. The assembly as claimed in claim 1, wherein a ratio of a modulus of rupture to a modulus of elasticity of the electrically conducting material is at least 1.1 times lower than the ratio of the material of the part of the filter to which the conducting material is secured.

5. The assembly as claimed in claim 1, wherein the electrically conducting material of the strip or the wire comprises at least one element selected from the group consisting of metallic conductors and ceramic conductors.

6. The assembly as claimed in claim 5, wherein the electrically conducting material has a metallic wire or tape arranged in contact with and secured to at least one of the monolithic element, the coating cement and the jointing cement.

7. The assembly as claimed in claim 5, wherein the electrically conducting material has of a strip of a ceramic material comprising particles of an electrically conducting material selected from the group consisting of metals of Fe, Ni, Si, Cr, and W group, metal alloys of Alumel, Inconel, NiCr, FeCr, SiCr, and MoSi₂, metal oxides of SnO₂, and Fe₂O₃, metal carbides of WC, B₄C, and SiC, and electrically conducting carbon.

8. The assembly as claimed in claim 7, wherein the ceramic material of the electrically conducting material comprises the same material as the material of the part of the filter to which the conducting material is secured.

9. The assembly as claimed in claim 5, wherein the electrically conducting material has a strip of an array of percolating conducting particles deposited on the material of the filter to which the conducting material is secured, said particles being selected from the group consisting of metals of Fe, Ni, Si, Cr, and W metal alloys of Alumel, Inconel, NiCr, FeCr, SiCr, and MoSi₂, or metal oxides of SnO₂, and Fe₂O₃, metal carbides of WC, B₄C, and SiC, and electrically conducting carbon.

10. The assembly as claimed in claim 1, wherein the wire or strip of conducting material is arranged at a periphery of the coating cement or embedded within the coating cement.

11. The assembly as claimed in claim 1, wherein the filter has a plurality of monolithic honeycomb elements bonded together by a jointing cement, and wherein the wire or strip of conducting material is arranged at a periphery of jointing cement or embedded in the jointing cement.

12. The assembly as claimed in claim 1, wherein the wire or strip of conducting material is arranged in contact with or inside the filtering part of the filter.

13. The assembly as claimed in claim 1, wherein said element or elements, the coating cement and the jointing cement have silicon carbide SiC.

14. A method of detecting one or more radial cracks in a particulate filter of honeycomb structure, by an assembly according to claim 1, comprising:
measuring a parameter selected from the group consisting of a voltage measurement, an AC current measurement, a DC current measurement, and a measurement of the electrical resistance wherein the measurement of the parameter is carried out upon start-up of a vehicle equipped with the filter continuously or at various predetermined instants in a predetermined temperature range,
comparing a value obtained against a threshold value for detection of a radial crack known as a “ring off” crack,
activating a signal to warn a driver or an operator that said cracks have appeared.

15. The method as claimed in claim 14, further comprising:
performing the comparison against the threshold value that is predefined, by a computer or by an electronic module connected to an engine control system, and
modifying, as a function of said comparison, engine management parameters or filter regeneration management device parameters in order to reduce a stress on the filter, by lowering a temperature at an inlet to the filter or reducing an oxygen content upstream of the filter.

16. The method as claimed in claim 14, further comprising:
performing the comparison against the threshold value that is predefined, by a computer or by an electronic module connected to a filter regeneration system, and
modifying, as a function of said comparison, management parameters of a filter regeneration system by reducing a limiting mass of soot.
